(19) United States
(12) Patent Application Publication
(10) Pub. No.: US 2008/0149370 A1
(43) Pub. Date: Jun. 26, 2008

(54) LOCAL TEMPERATURE CONTROL FIXTURE APPLIED TO REFLOW PROCESS FOR CIRCUIT BOARD

(75) Inventors: Hsiu-Feng Lee, Taipei City (TW); Ming-Xiang He, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: COMPAL ELECTRONICS, INC., Taipei City (TW)

(21) Appl. No.: 11/842,178

(22) Filed: Aug. 21, 2007

(30) Foreign Application Priority Data
Dec. 20, 2006 (TW) 95147908

(51) Int. Cl. H05K 1/00

(52) U.S. Cl. 174/252

(57) ABSTRACT

A local temperature control fixture suitable for a circuit board is provided, and the circuit board has at least a first heat-receiving region. The fixture includes a heat-insulating board. The heat-insulating board is positioned over the circuit board suitably and has at least a first exposing region whose projection on the circuit board is superposed with the first heat-receiving region. Furthermore, by means of the local temperature control fixture, components on the circuit board can be properly heated according to the volumes thereof so as to melt solder between the components and the circuit board. Therefore, the components in different sizes are firmly soldered onto the circuit board.

### CROSS-REFERENCE TO RELATED APPLICATION

This application claims the priority benefit of Taiwan application serial no. 95147908, filed Dec. 20, 2006. All disclosure of the Taiwan application is incorporated herein by reference.

### BACKGROUND OF THE INVENTION

1. Field of the Invention

The present invention generally relates to a local temperature control fixture, and more particularly, to a local temperature control fixture applied to a reflow process for a circuit board.

2. Description of Related Art

A motherboard of a desktop computer or a notebook computer has various electronic components fixed thereon and being in charge of different functions. For example, a motherboard has some ports available for being connected with peripherals, such as a keyboard, a mouse and a printer, etc. and also has some electronic components, such as chip set, CPU socket, memory slot connectors, interface card slot connectors, capacitors, etc.

During assembling electronic components on a motherboard, at first, a circuit board is provided. Next, solder paste has to be spread on pads of the circuit board waiting for placing the electronic components thereon. Then, terminals of the electronic components are placed on solder paste on the circuit board. In the end, a reflow process is conducted so that the electronic components are fixed on the circuit board and electrically connected to the circuit board by solder. During the reflow process, the solder must be sufficiently melted, so that the electronic components are firmly fixed on the circuit board by the solder.

However, there are many kinds of components on a same motherboard, and the kinds of components have various functions and different volume. Therefore, during a reflow process, a bigger component requires a higher heated temperature for melting solder between the bigger component and the corresponding pads. To meet the requirement occurred with the bigger component, the reflow temperature can be increased; but such a solution often causes an extreme temperature for a smaller component where an overhigh temperature may burn the smaller component and leave a discolored appearance to the smaller component, even make the smaller component crisp or damaged. Therefore, how to solve the above-mentioned problem is critical in the case where all components in different sizes are disposed on a same circuit board and the heated temperatures required thereby are very different.

### SUMMARY OF THE INVENTION

Accordingly, the present invention is directed to a local temperature control fixture, which can make components on a circuit board properly heated according to their different volumes during a reflow process so that the components in different sizes are able to be firmly soldered on the circuit board.

As embodied and broadly described herein, the present invention provides a local temperature control fixture suitable for a circuit board having at least a first heat-receiving region. The fixture includes a heat-insulating board. The heat-insulating board is suitable to be positioned over the circuit board, and has at least a first exposing region, and a projection of the first exposing region on the circuit board is superposed with the first heat-receiving region.

In an embodiment of the present invention, the first exposing region may include at least an opening.

In an embodiment of the present invention, the first exposing region may include a hole with non-integral edge located at a side edge of the heat-insulating board.

In an embodiment of the present invention, the circuit board may have at least a second heat-receiving region, wherein a heated temperature required by the second heat-receiving region is lower than a heated temperature required by the first heat-receiving region. The heat-insulating board may have at least a second exposing region, a projection of the second exposing region on the circuit board is superposed with the second heat-receiving region and a exposure area of the second exposing region is less than a exposure area of the first exposing region.

In an embodiment of the present invention, the second exposing region may include at least an opening.

In an embodiment of the present invention, the second exposing region may include a hole with non-integral edge located at a side edge of the heat-insulating board.

In an embodiment of the present invention, the circuit board may further have at least a third heat-receiving region, wherein a heated temperature required by the third heat-receiving region is lower than a heated temperature required by the second heat-receiving region. The heat-insulating board may further have at least a third exposing region, a projection of the third exposing region on the circuit board is superposed with the third heat-receiving region and a exposure area of the third exposing region is less than a exposure area of the second exposing region.

In an embodiment of the present invention, the third exposing region may include at least an opening.

In an embodiment of the present invention, the third exposing region may include a hole with non-integral edge located at a side edge of the heat-insulating board.

In an embodiment of the present invention, the local temperature control fixture may further include positioning components connected to the heat-insulating board to position the heat-insulating board over the circuit board.

In an embodiment of the present invention, the positioning components may be detachably connected to the heat-insulating board.

In an embodiment of the present invention, each of the positioning components may include a bolt, a first nut and a second nut, wherein the first nut is to fix the bolt on the heat-insulating board and the second nut is threaded on the bolt. When the segments of the bolts are respectively inserted into through holes of the circuit board, the second nuts function for keeping the heat-insulating board from the circuit board in an interval.

According to the above described, the present invention features that the heat-receiving regions are defined on the circuit board to suit the heated temperatures required by some components on the circuit board, and one to several exposing regions corresponding to the heat-receiving regions on the circuit board are further defined on the heat-insulating board of the local temperature control fixture. Thus, the quantity of incoming heat of the heat-receiving regions during reflow can be controlled by the exposed areas of the exposing regions, and the heated temperatures of the components located at the heat-receiving regions on the circuit board are adjustable to meet the needs thereof, which makes the components on a same circuit board respectively and properly heated according to their different volumes, and thus the solder between the components and the circuit board can be fully melted so as to firmly solder all the components in different sizes on the circuit board.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an exploded drawing of a local temperature control fixture with a motherboard prior to assembly according to an embodiment of the present invention.

FIG. 2 is an exploded drawing of a local temperature control fixture with a motherboard after assembly in FIG. 1.

FIG. 3 is a locally enlarged sectional diagram of area A in FIG. 2.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

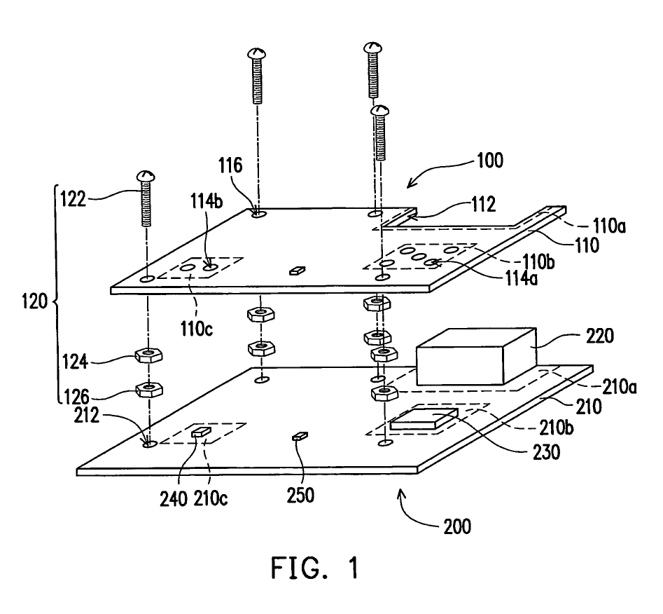

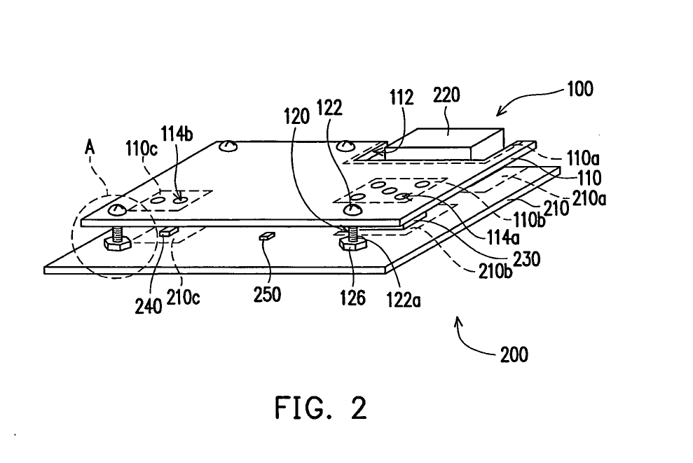

FIG. 1 is an exploded drawing of a local temperature control fixture with a motherboard prior to assembly according to an embodiment of the present invention and FIG. 2 is an exploded drawing of a local temperature control fixture with a motherboard after assembly in FIG. 1. Referring to FIGS. 1 and 2, a local temperature control fixture 100 includes a heat-insulating board 110. The heat-insulating board 110 is suitable to be positioned over a circuit board 210 of a motherboard 200.

Comparing other components 230, 240 and 250, the component 220 on a first heat-receiving region 210a of the circuit board 210 has a bigger volume and is a connector, for example. Thus, the component 220 requires a higher heated temperature during reflow to make the solder between the component 220 and the circuit board 210 fully melted. Since the component 220 has a bigger volume, the first heat-receiving region 210a accordingly requires a higher heated temperature.

In order to control the quantity of heat conducted to the first heat-receiving region 210a of the circuit board 210 during reflow, the heat-insulating board 110 has a first exposing region 110a, wherein the projection of the first exposing region 110a on the circuit board 210 is superposed with the first heat-receiving region 210a on the circuit board 210.

Referring to FIG. 2, after assembling the local temperature control fixture 100 with the motherboard 200, the first exposing region 110a allows the component 220 on the motherboard 200 to be exposed beyond the heat-insulating board 110. Thus, the component 220 can be fully heated during reflow, so that the solder between the component 220 and the circuit board 210 is melted to complete soldering, while other smaller components 230, 240 and 250 are insulated from partial heat by means of the heat-insulating board 110, which is helpful to prevent other smaller components 230, 240 and 250 from being overheated, burned or damaged.

In the embodiment, the first exposing region 110a includes a hole 112 with non-integral edge located at an edge of the heat-insulating board 110 and corresponding to the exposed first heat-receiving region 210a to make the component 220 properly exposed beyond the heat-insulating board 110. In addition, in another embodiment not shown, the first exposing region 110a can also include openings corresponding to the exposed first heat-receiving region 210a, so that the component 220 is properly exposed beyond the heat-insulating board 110.

In this way, the components 220, 230, 240 and 250 on the circuit board 210 are properly heated depending on the volumes thereof by using the local temperature control fixture 100 during reflow, which makes the solder melted for soldering between the components 220, 230, 240 and 250 and the circuit board 210, so that the components 220, 230, 240 and 250 in different sizes are able firmly soldered on the circuit board 210 in a same reflow process.

In the embodiment, to suit the different heated temperatures required respectively by the components 230 and 240 on the motherboard 200, the circuit board 210 has also a second heat-receiving region 210b and a third heat-receiving region 210c, on which the components 230 and 240 are located respectively. Accordingly, the heat-insulating board 110 has a second exposing region 110b and a third exposing region 110c, which expose the second heat-receiving region 210b and the third heat-receiving region 210c beyond the heat-insulating board 110 respectively.

In the embodiment, the second exposing region 110b may have some openings 114a, and there are five openings shown in FIGS. 1 and 2, for example, but the present embodiment does not limit the quantity, shape and size of the openings 114a except the openings 114a are required to be distributed substantially evenly in the second exposing region 110b. In another embodiment not shown, the second exposing region 110b can include a hole with non-integral edge at an edge of the heat-insulating board 110 as well.

Since the component 230 on the second heat-receiving region 210b has a smaller volume than the volume of the component 220 and is, for example, a chip set, the heated temperature, required by the component 230 on the second heat-receiving region 210b and enough to make the solder between the component 230 and the circuit board 210 fully melted, would be lower than that required by the component 220 on the first heat-receiving region 210a. Accordingly, the exposed area of the second exposing region 110b should be less than that of the first exposing region 110a to create the heated temperature of the second heat-receiving region 210b lower than that of the first heat-receiving region 210a.

In order to control the quantity of heat conducted to the second heat-receiving region 210b on the circuit board 210 during reflow, the projection of the second exposing region on the circuit board 210 is superposed with the second heat-receiving region 210b on the circuit board 210.

In the present embodiment, the third exposing region 110c can also have some openings 114b, and there are two openings shown in FIGS. 1 and 2, for example, but the present embodiment does not limit the quantity, shape and size of the openings 114b except the openings 114b are required to be distributed substantially evenly in the third exposing region 110c. In another embodiment not shown, the third exposing region 110c can include a hole with non-integral edge at an edge of the heat-insulating board 110 as well.

Since the component 240 on the third heat-receiving region 210c has a smaller volume than the volumes of the components 220 and 230 and is, for example, a capacitor, the heated temperature, required by the component 240 on the third heat-receiving region 210c and enough to make the solder between the component 240 and the circuit board 210 fully melted, would be lower than that required by the component 230 on the second heat-receiving region 210b. Accordingly, the exposed area of the third exposing region 110c should be less than that of the second exposing region 110b to create the heated temperature of the third heat-receiving region 210c lower than that of the second heat-receiving region 210b.

In order to control the quantity of heat conducted to the third heat-receiving region 210c on the circuit board 210 during reflow, the projection of the third exposing region on the circuit board 210 is superposed with the third heat-receiving region 210c on the circuit board 210.

In the present embodiment, by properly disposing the exposing regions 110a, 110b and 110c on the heat-insulating board 110 according to the sizes of the components 220, 230, 240 and 250 and the required heated temperatures thereof, the bigger components 220, 230 and 240 are heated in different doses and the smaller component 250 is totally covered by the heat-insulating board 110 so as to control the heated temperatures of the components 220, 230, 240 and 250.

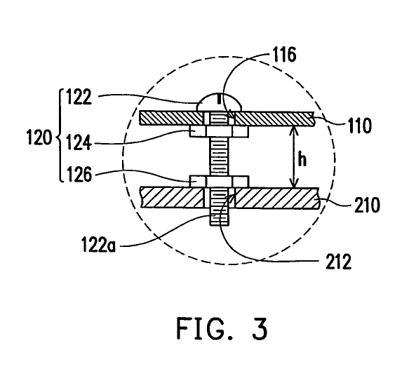

FIG. 3 is a locally enlarged sectional diagram of area A in FIG. 2. Referring to FIGS. 2 and 3, the local temperature control fixture 100 can further include positioning components 120 connected to the heat-insulating board 110 to position the heat-insulating board 110 over the circuit board 210. Each positioning component 120 includes a bolt 122, a first nut 124 and a second nut 126. The bolt 122 goes through a through hole 116 of the heat-insulating board 110 and is fixed on the heat-insulating board 110 by the first nut 124, while the second nut 126 is also threaded on the bolt 122. After the segments 122a of the bolts 122 are respectively inserted into through holes 212 of the circuit board 210, the second nuts 126 function to keep the heat-insulating board 110 from the circuit board 210 in an interval h, wherein the interval h is adjustable to suit the heights of the components relative to the circuit board 210 after soldering.

In summary, when performing a reflow process to melt solder between the components and the circuit board, the heated temperatures of the components located on different heat-receiving regions can be controlled by adjusting the exposed areas of the exposing regions relative to the heat-receiving regions of the circuit board by the local temperature control fixture of the present invention. Therefore, the reflow temperature can be appropriately set to higher, so that the components requiring higher heated temperatures are heated adequately and the corresponding solder is fully melted to achieve the soldering effect. In addition, after increasing the reflow temperature, the sizes of the exposing regions on the heat-insulating board corresponding to the components are properly adjusted, which functions not only to provide sufficient heat, but also to isolate the components requiring lower heated temperatures from unnecessary heat, so that the components are not discolored or damaged due to an overheat. That is to say, the present invention is able to make the components, no matter the sizes thereof, firmly soldered on a circuit board and to prevent the components from damage and avoid the problems encountered by the prior art.

Besides, by using positioning components to position the heat-insulating board over the circuit board and to adjust the distance between the heat-insulating board and the circuit board, the present invention is able to avoid a structure interfere of the heat-insulating board with the components to be soldered on the circuit board. A user even is allowed to easily manipulate the heat-insulating board by hand, for example, to place the heat-insulating board onto the circuit board or take the heat-insulating board away from the circuit board.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A local temperature control fixture, suitable for a circuit board having a first heat-receiving region, the fixture comprising:
a heat-insulating board, positioned over the circuit board and having a first exposing region, wherein the projection of the first exposing region on the circuit board is superposed with the first heat-receiving region.

2. The local temperature control fixture according to claim 1, wherein the first exposing region comprises an opening.

3. The local temperature control fixture according to claim 1, wherein the first exposing region comprises a hole with non-integral edge located at a side edge of the heat-insulating board.

4. The local temperature control fixture according to claim 1, wherein the circuit board further has a second heat-receiving region, the heated temperature required by the second heat-receiving region is lower than the heated temperature of the first heat-receiving region, the heat-insulating board further has a second exposing region, the projection of the second exposing region on the circuit board is superposed with the second heat-receiving region and the exposure area of the second exposing region is less than the exposure area of the first exposing region.

5. The local temperature control fixture according to claim 4, wherein the second exposing region comprises an opening.

6. The local temperature control fixture according to claim 4, wherein the second exposing region comprises a hole with non-integral edge located at a side edge of the heat-insulating board.

7. The local temperature control fixture according to claim 1, further comprising:
a plurality of positioning components connected to the heat-insulating board so as to position the heat-insulating board over the circuit board.

8. The local temperature control fixture according to claim 7, wherein the positioning components are detachably connected the heat-insulating board.

9. The local temperature control fixture according to claim 7, wherein each of the positioning components comprises a bolt, a first nut and a second nut, the first nut is to fix the bolt on the heat-insulating board and the second nut is threaded on the bolt, so that when the segments of the bolts are respectively inserted into a plurality of through holes of the circuit board, the second nuts function for keeping the heat-insulating board from the circuit board in an interval.
